(19) United States
(12) Patent Application Publication
(10) Pub. No.: US 2022/0260915 A1
(43) Pub. Date: Aug. 18, 2022

(54) BEAM COLLIMATION TOOL

(71) Applicant: Microsoft Technology Licensing, LLC, Redmond, WA (US)

(72) Inventors: Peter Krogstrup Jeppesen, Copenhagen (DK); Pasi Kostamo, Helsinki (FI); Tomas Stankevic, Copenhagen (DK)

(73) Assignee: Microsoft Technology Licensing, LLC, Redmond, WA (US)

(21) Appl. No.: 17/597,838

(22) PCT Filed: Jul. 29, 2019
(86) PCT No.: PCT/EP2019/070387

§ 371 Date: Jan. 25, 2022

(51) Int. Cl. G03F 7/12; C23C 16/04

(52) U.S. Cl. CPC G03F 7/12; C23C 16/45536; C23C 16/042

(57) ABSTRACT

A method for collimating a beam of material being deposited on a substrate at a deposition area of the substrate is disclosed. The substrate is masked with a stencil mask located at a mask distance from the substrate, the mask distance being the distance between a top face of the substrate and an outer face of the mask facing the substrate. The beam is projected from a source cell located at a source distance from the mask, the source distance being the distance between the source cell and an outer face of the mask facing the source cell. The stencil mask comprises two mask layers separated by a layer separation distance which is great than zero. Each mask layer comprises a slit, the slits of the two layers having a width being aligned in a plane of the substrate.

### TECHNICAL FIELD

This application relates to a method and apparatus for collimating a beam.

### BACKGROUND

The fabrication of microscale and nanoscale devices such as semiconductor dies, quantum computing devices and optical waveguide structures, will typically involve building up a substrate through the deposition of multiple layers of material in different patterns over a wafer. The overall process will involve multiple steps as the different layers are built up. Though the terminology is not always used consistently in the art, for the present purposes the “wafer” will be taken herein to refer to the base layer, and the “substrate” will refer to the wafer and any additional layers which may have been added to the wafer up to the present point in the fabrication process.

For example, in the fabrication of a traditional semiconductor device, the wafer comprises a semiconductor such as silicon with differently doped n- and p-type regions. The material being deposited at any given subsequent layer may then for example be a conductor, a further layer of semiconductor, or a dielectric or other insulator (with different kinds of material typically being deposited at different respective layers). In the case of fabricating a quantum electronic device such as a quantum computing device, the wafer may be a semiconductor or an insulator, and the deposited materials may be conductors, insulators, semiconductors and/or superconductors. For instance, as a basis for a quantum circuit, lines of semiconductor are formed over an insulating substrate, and then a coating of superconductor is formed over the semiconductor lines to form a network of semiconductor-superconductor nanowires.

Vacuum deposition refers to fabrication techniques whereby a layer of material is deposited onto a substrate while in vacuum within a vacuum chamber. The material may for example be deposited in the form of a molecular or atomic beam flux (directional). The material is initially deployed in its source form (e.g. liquid or solid) in a source cell, which is located in the vacuum chamber or has an opening into the vacuum chamber. The material is then energized in the source cell such as through heating or ionization, causing it to be projected from the source cell through the vacuum toward the substrate, which is also deployed in the vacuum chamber. For instance, one form of vacuum deposition is molecular beam epitaxy. In this case a source cell is arranged to heat the source material, causing it to evaporate or sublime. The source cell is arranged to eject the evaporated or sublimated molecules or atoms through the vacuum toward the substrate in the form of a molecular or atomic beam. The particles then condense on the substrate in a crystalline form. Other forms of vacuum deposition are also known, such as chemical beam epitaxy, or thin film deposition systems (e.g. E-beam evaporation, thermal evaporation or Ion milling). Various forms of vacuum deposition and the various material that can be deposited to form various kinds of structure will, in themselves, be familiar to a person skilled in the art.

To form the desired pattern, the traditional approach is lithography which uses a photo resist as a mask. A patterned photo resist, i.e. a photo mask, is deposited on the substrate and then a pattern is defined by shining light (UV) through the photo resist. The illuminated areas react by changing their chemical composition. Openings are then washed out after chemically developing the resist. These openings can be used either to etch the underlying material through them or deposit subsequent materials. Thus, photoresist acts as a kind of mask. After that the photo resist is removed using solvents.

Other, less conventional techniques may employ a shadow mask as a separate object (not a layer or structure deposited on the substrate). In this case the mask comprises a pattern of perforations defining a structure to be formed on the underlying substrate. Such a mask may also be referred to as a stencil type mask, as opposed to a photo mask. The material is projected from the source through the mask onto the substrate, so as to be deposited only where the mask is perforated (i.e. only where the gaps or holes are). The material then solidifies on the underlying substrate and thus grows a structure on the substrate, with a pattern corresponding to that of the perforations in the mask. On another point of terminology, note that “over” or such like herein does not necessarily mean with respect to gravity, but rather is to be understood in the sense of covering the wafer (or at least part thereof) on the side being worked, i.e. the side upon which the deposition is currently being performed. In the case of the mask this means between the wafer and the source (though not necessarily in physical contact with the wafer). A reciprocal interpretation should also be given to terms such as “underlying”.

### SUMMARY

The inventors have identified the problem of realising small structures such as nano-size structures with little line broadening due to the geometry and setup of the fabrication system. The distance between the substrate and the opening angle subtended by the source from the perforations in the mask determine the broadening of features in the prior art. The dependency of the accuracy of the nanostructures produced to these dimensions presents challenges for fabricating defined features accurately.

The inventors have devised a stencil mask comprising two mask layers which collimate the incoming beam of atoms, thus making the line broadening dependent on the geometry of the stencil mask instead of the geometry of the overall fabrication setup.

According to one aspect disclosed herein there is provided a method for collimating a beam of material being deposited on a substrate at a deposition area of the substrate, the method comprising: masking the substrate with a stencil mask located at a mask distance from the substrate, the mask distance being the distance between a top face of the substrate and an outer face of the mask facing the substrate; and projecting the beam from a source cell located at a source distance from the mask, the source distance being the distance between the source cell and an outer face of the mask facing the source cell; wherein the stencil mask comprises two mask layers separated by a layer separation distance which is great than zero, each layer comprising a slit, the slits of the two layers having a width being aligned in a plane of the substrate.

According to a second aspect disclosed herein, there is provided a stencil mask comprising: two mask layers; a separation layer which separates the two mask layers by a layer separation distance which is greater than zero; wherein each mask layer comprises a slit, the slits being aligned in a plane of the mask; wherein the separation layer comprises a void which is aligned with the slits in the plan of the mask and is wider than the slits.

According to a third aspect of the present disclosure, there is provided a method for fabricating the stencil mask, the method comprising: growing a first of the two mask layers on a first wafer; patterning said first mask layer; growing a second of the two mask layers on a second wafer; patterning said second mask layer; and affixing the two wafers together, such that the two mask layers are separated by the two wafer layers, the two wafer layers having a combined thickness equal to the layer separation distance.

### BRIEF DESCRIPTION OF THE DRAWINGS

For better understanding of the present invention, and to show how embodiments may be carried into effect, reference is made, by way of example only, to the following figures.

FIG. 1 shows an example deposition method using a single-layered stencil mask,

FIG. 2 shows an example plan view of a mask layer,

FIG. 3 shows an example of a double-layered stencil mask used in material deposition,

FIG. 4 shows a schematic top view of a quantum circuit comprising SE//SU nanowires and side-gate regions, and

FIGS. 5a-5d are schematic diagrams of SE//SU nanowires formed on a substrate.

### DETAILED DESCRIPTION OF THE INVENTION

As described above, stencil masks may be used to produce semiconductor-superconductor (SE/SU) elements for use in, for example, quantum computing. During the fabrication process, a deposition material is deposited on a substrate. The substrate may comprise a silicon wafer with semiconducting nanowires on it, for example. The wafer may be an insulating GaAs wafer, or it may be a silicon wafer. The nanowires may be grown using selective area growth (SAG). The nanowires may, for example, be made of InAs.

The deposition material is deposited in a desired pattern on the substrate in order to form the required features on the substrate. Such features may include contacts for wires, superconducting (SU) elements, or a SU coating. The deposition material may be a superconductor, such as aluminium. The apparatus and method described herein may also be used to produce dielectric elements, where a dielectric deposition material is used. It could also be used when the deposition material is a metal or a semiconductor. The fabrication processes described herein may be performed in a vacuum.

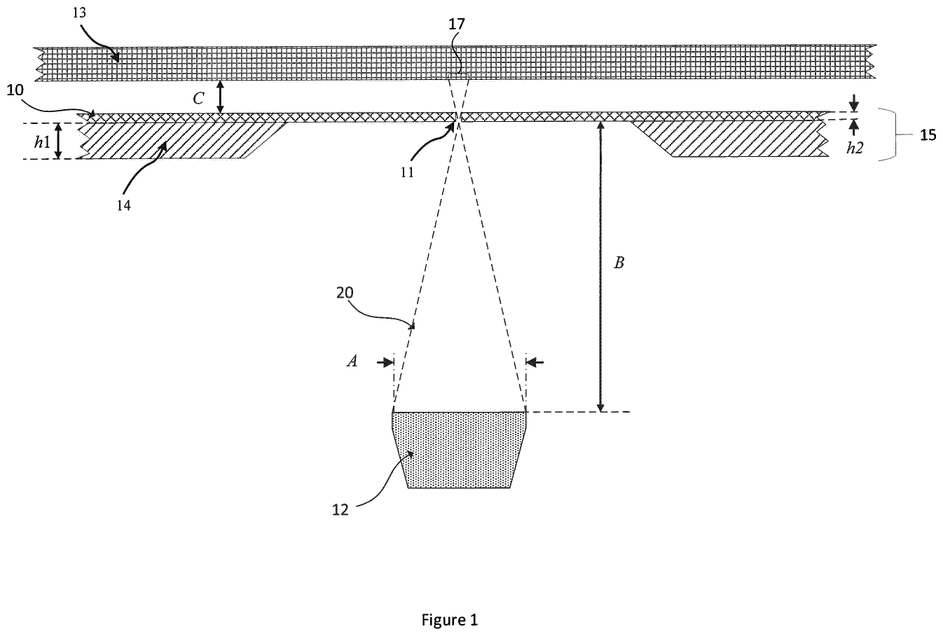

FIG. 1 illustrates an example of a method of material deposition using a stencil mask 15 known in the art. The set-up includes the stencil mask 15, a source cell 12, and a substrate 13. The source cell 12 is positioned at a source distance B from the stencil mask 15. The source distance is defined as the distance between the source cell 12 and the outer face of the mask layer which faces the source. The stencil mask 15 is located at a mask distance C from the substrate. The mask distance is defined as the distance between the top face of the substrate, i.e. the face closest to the mask and on which the deposition material is deposited, and the outer face of the mask layer facing the substrate.

The source cell 12 contains the deposition material to be deposited on the substrate 13 in its source from. In order for the material to be deposited, the deposition material at the source is energised. This can be achieved by heating the material, for example via resistive or indicative heating, so that the material evaporates or sublimes. Alternatively, the source material may be ionised. Once the source material has been energised, it can be released from the source cell 12 as a beam 20 and projected towards the substrate 13. The source cell has a width A which is defined as the width from which the energised deposition material bean 20 is projected.

The stencil mask 15 is positioned between the source cell 12 and the substrate 13, so masking the substrate from some of the deposition material projected from the source cell 12. It comprises a single mask layer 10 formed on a wafer 14. The mask layer 10 contains a slit 11, through which the deposition material in the beam 20 passes. The slit 11 is, therefore, used to define an incident area on the substrate 13 at which the beam 20 is incident. In material deposition, the incident area may also be referred to as a deposition area 17. The material in the beam 20 is deposited at the deposition area 17, where it condenses to form a crystalline structure.

Using the set-up shown in FIG. 1, the size of the deposition area 17 is dependent on the size of the slit 11, the source width A, the source distance B, and the mask distance C.

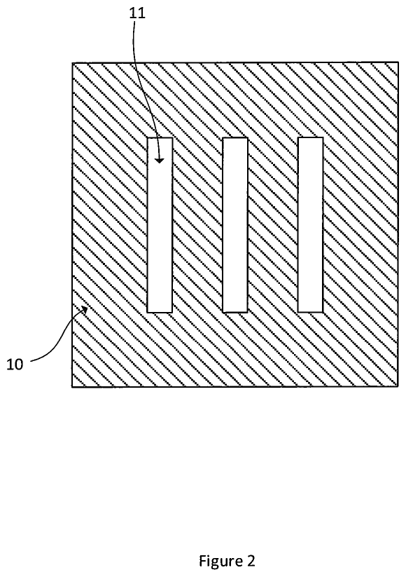

FIG. 2 shows a plan view of an example mask layer 10. This mask layer 10 contains three slits 11 which are equal spaced, each slit having the same dimensions, with the length being greater than the width. Although the term slit has been used in the present disclosure, it will be appreciated that this term refers to apertures in the mask layer 10, and that such apertures may be of different shapes. There may be one or more aperture per mask layer 10. The apertures may be the same shape and dimensions, or they may be different shapes and dimensions. The apertures in the mask layer 10 are determined by the desired deposition pattern of the deposition material on the substrate 13. The desired pattern is defined by the elements which are to be created on the substrate using the deposition material.

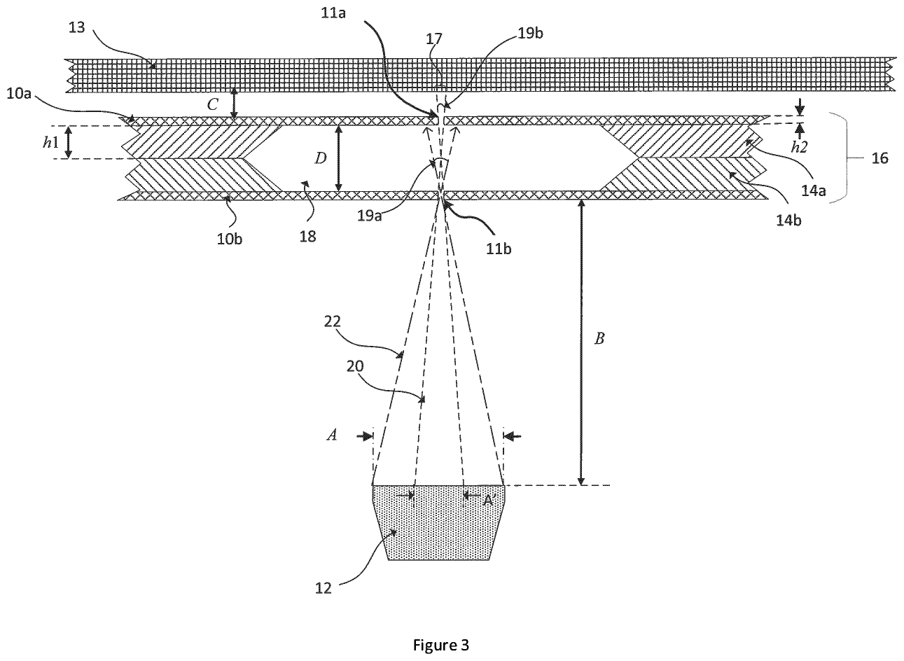

FIG. 3 illustrates an example of an improved stencil mask 16 for collimating a beam according to the present invention. The stencil mask 16 collimates the beam more strictly than the angle defined by the source cell 12 itself, such that the deposition area 17 is smaller than if no stencil mask 16 were present. The stencil mask 16 also collimates the beam 20 more strictly than the single-layered stencil mask 15 shown in FIG. 1, as discussed below.

The stencil mask 16 comprises two mask layers 10a, 10b. The two mask layers 10a, 10b are separated by a layer separation distance D which is greater than zero. There is a separation layer between the two mask layers 10a, 10b. In this example, the separation layer comprises two wafers 14a, 14b, which may be, for example, silicon wafers. It will be appreciated that the separation layer may comprise a single layer or multiple layers. It may be made of silicone or a different material. The layers within the separation layer may be made of the same material as each other, or they may be different materials. In the example of FIG. 3, the two wafers 14a, 14b forming the separation layer have equal depths h₁, where D2 h₁. However, it will be appreciated that, if there is more than one layer of material forming the separation layer, as in FIG. 3, the layers need not be equal in depth. The layer separation distance may be between 100 μm and 1 mm. The mask layers 10a, 10b are also shown to be equal in depth, with a depth of h₂. It will be appreciated that this depth does not need to be the same for each mask layer 10a, 10b of the stencil mask 16. These mask layers 10a, 10b may have a depth of between 20 nm and 200 nm. The mask layers 10a, 10b may be made of silicon nitride or silicon, for example. The formation of the stencil mask 16 is described later.

The mask layers 14a, 14b each contain a slit 11a, 11b. These slits 11a, 11b are aligned in a plane of the substrate. It will be appreciated that the slits 11a, 11b are also aligned in the plane perpendicular to the beam, such that the beam 20 of deposition material passes through both slits 11a, 11b to reach the substrate 13. The slits 11a, 11b in the two layers need not be identical in size, however there is an improved collating effect if the slits 11a, 11b are the same size or if the slit 11b closest to the source cell 12 is smaller than the slit 11a closest to the substrate 13. It will be appreciated that there may be more than one slit in each mask layer 10a, 10b, as shown in the example mask layer 10 of FIG. 2.

The use of the double-layered stencil mask 16 provides a means for collimating the beam 20. FIG. 3 shows a beam 22 of deposition material projected from the entire surface of the source cell 13 which is able to pass through the slit 11b closest to the source cell 12. It can be seen that the beam 22 is narrowest when passing through the slit 11b, and spreads after passing through this slit such that some of the material in the beam cannot pass through the second slit 11a. The material which does not pass though the second slit 11a does not reach the substrate 13. Thus, for a given slit size 11b, the deposition area 17 is reduced. This double-layered stencil mask 16 effectively reduces the source cell width from A to A′.

It should be noted that the source cell 12 projects deposition material from its entire width A, but only material projected from the reduced effective source cell width A′ is deposited on the substrate 13.

On passing through the first slit 11b, the beam has a first opening angle 19a. This angle is a function of the width of the first slit 11b and the source distance B. The second slit 11a through which the beam passes has the effect of reducing the opening angle of the beam exiting the stencil mask 16 to a second opening angle 19b. This second opening angle 19b is a function of the layer separation distance and the width of the second slit 11a. The deposition area 17 is a function of the second opening angle 19b. The second slit 11a effectively removes the dependency of the deposition area 17 on the source distance B and the mask distance C.

The advantage of the double-layered stencil mask 16 over the stencil mask 15 shown in FIG. 1 is that the dimensions of the deposition area 17 are almost independent of the mask distance C and the source distance B. The geometry of the deposited material is primarily defined by the patterning of the apertures of the stencil mask 16 itself and the layer separation distance. Therefore, the distances of the elements of the apparatus need not be set as accurately as when a single layer stencil mask 15, i.e. a single mask layer 10, is used, so increasing the speed at which the apparatus can be set up. Additionally, since the effective source cell width is reduced, there is less spreading of the beam between the stencil mask 16 and the substrate 13 so it is easier to produce nanometre scale patters without a blurring effect.

The source distance B may be between 20 cm and 1 m. The mask distance C may be between 1 μm and 10 μm. The source cell width A may be between 5 mm and 50 mm. For a given source cell width A, source distance B, mask distance C, and slit width, the deposition area 17 is smaller when the double-layered stencil mask 16 is used instead of the single-layered stencil mask 15.

It can be seen from FIG. 3 that there is a void 18 in the separation layer. A void 18 is required, aligned with the slits 11a, 11b in the plane perpendicular to the beam, which is also the plane of the mask layer and the plane of the substrate, and at least equal in dimensions in plan to the slits 11a, 11b so that the deposition material beam 20 can pass through the stencil mask 16 and reach the substrate 13. The void 18 of FIG. 3 is shown to be wider than the slits 11a, 11b. It may also be longer that the slits 11a, 11b. It is advantageous for the void 18 to have one or more dimension greater than the slits 11a, 11b so that the deposition material in the beam 22 which cannot pass through the second slit 11a does not block the pathway through the stencil mask 16. Instead, it is deposited on an inner surface of the mask layer 10a closest to the substrate 13. This allows the stencil mask 16 to be re-used to create the same pattern.

It will be appreciated that, although the stencil mask 16 illustrated in FIG. 3 comprises two mask layers 10a, 10b, the stencil mask 16 for collimating the beam 20 may comprise more than two mask layers.

Using the materials discussed above, the resulting structure is a SE/SU component. It will be appreciated that the stencil mask 16 and the methodology described above may be used to produce other types of components when different materials are used as the substrate 13 and the deposition material. For example, the stencil mask 16 may be used to fabricate optical devices. Examples of such devices include waveguides, optical resonators, and diffraction gratings.

The stencil mask 16 may be fabricated via the following steps.

On a blank wafer 14a for use as one of the layers of the separation layer, the mask layer 10a is grown to its desired thickness. The mask layer 10a may be grown via low pressure chemical vapour deposition (LPCVD). The mask layer 10a is then patterned with the desired pattern of the apertures of the stencil mask 16. Patterning may be achieved using etching or a lithographic technique, such as photolithography. Other techniques such as mechanical patterning may be used to define and produce the pattern of apertures in the mask layer 10a.

The second mask layer 10b is grown on a second blank wafer 14b for use as the second layer of the separations layer. The mask layer 10b may be grown using the same techniques as the first mask layer 10a, or a different technique may be used. The second mask layer 10b is patterned. Again, this may be using the same technique or a different technique to that used for the first mask layer 10a.

Once both mask layers 10a, 10b have been patterned, the two halves of the stencil mask 16 are fixed together such that the mask layers 10a, 10b are on the outside of the stencil mask 16. That is, the exposed faces of the wafers 14a, 14b are affixed. Methods for affixing two silicon wafers are known in the art. The two wafers 14a, 14b form the separation layer of the stencil mask 16, such that the total thickness of the two wafers is equal to the layer separation distance D.

For a stencil mask 16 which comprises more than two layers, the steps of growing the mask layer on a wafer and patterning the mask layer are performed for the additional layers. These are then affixed to the double-layered stencil mask to form a stencil mask comprising more than two mask layers 10.

In some embodiments, there may be more than two wafers forming the separation layer of the stencil mask 16. Additional wafers may be introduced to increase the separation distance. A third wafer may, for example, be affixed to the exposed faces of the two wafers 14a, 14b such that the separation layer is formed of three wafers. It will be appreciated that any number of additional wafers may be introduced between the wafers 14a, 14b on which the mask layers 10a, 10b have been grown.

In the above embodiments, the source cell 12 has produced a beam 20 of the deposition material, such that the deposition of the material is directional. Directional deposition of the deposition material is preferable, however, any physical vapour deposition (PVD) method may be used. Other material projection methods may be used which project the deposition material at the substrate in a multi-directional manner. For example, plasma-enhanced chemical vapour deposition (PECVD) or sputter deposition may be used to project the deposition material. The disadvantage of using a multi-directional deposition method is that the there is an increase of the rate at which material is deposited on the side walls of the apertures in the stencil mask compared to when a beam deposition method is used. This decreases the reusability of the stencil mask, and, in some cases, the apertures may become blocked at a rate which is too high for the stencil mask to be used in practice. Thus, the use of multi-directional material deposition in the fabrication process may reduce the scalability of fabrication of the resultant components.

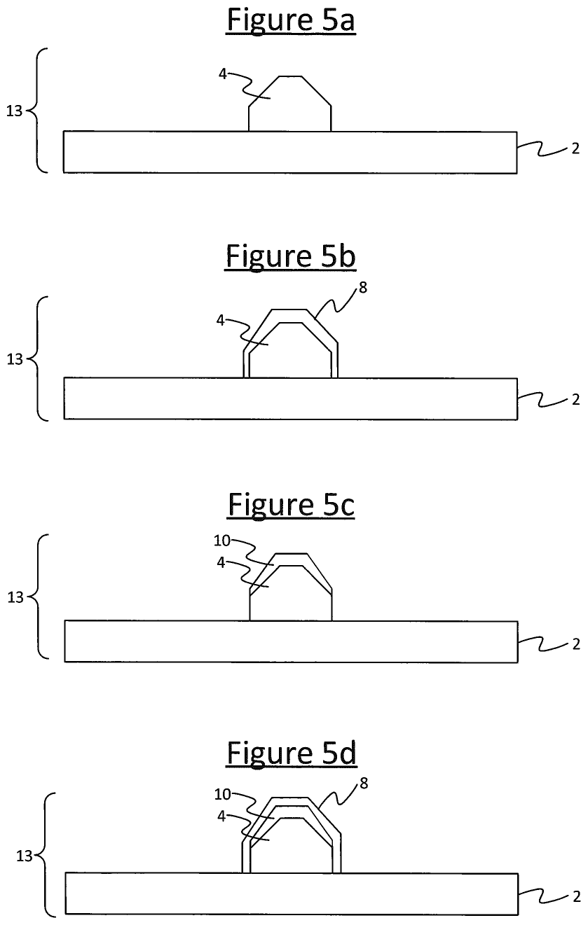

FIG. 5a illustrates an example device (or part thereof). The device comprises a substrate 13 comprising a wafer 2 and multiple layers formed over the wafer 2. The multiple layers comprise at least a first layer comprising structured portions of semiconductor 4. There may, for example, be one or more intervening layers between the wafer 2 and the semiconductor 4, such as a semiconductor or dielectric layer.

The portions of semiconductor 4 are formed over the wafer 2 by any suitable known deposition technique. Although not shown, there may be a coating of ferromagnetic insulator grown at least partially on each of some or all of the semiconductor portions 4. This layer may be grown by means of epitaxy.

Optionally one or more further layers may be formed over semiconductor 4. FIG. 5b illustrates one example whereby an oxide layer 8 is formed over part or all of each semiconductor structure 4 (or at least some of the semiconductor structures). The oxide layers can be used to protect the semiconductor structures 4 against O2 or H2O in air. They may be used to protect samples in TEM (transmission electron microscopy) or for the reflective layer in PNR (polarized neutron reflectivity). The oxide layer 8 could be for example silicon oxide, SiOx; or more generally any dielectric or other insulating material could be used in its place. Note however that the oxide layer 8 is optional, and in other cases this protection may not be required, or could be provided by other upper layers of the substrate or IC package (not shown).

In some cases, the oxide layer 8 may be used only in samples during experimentation stages, or as an intermediate step in the fabrication, but may not remain in the final product.

FIG. 5c illustrates an example where a coating of superconductor material 10 is formed over part or all of each semiconductor 4 (or at least some of the semiconductor 4). In embodiments, at least some of the semiconductor structures 4 each comprise a length or line of the semiconductor material 4. In this case FIG. 5c represents a cross section in the plane perpendicular to the line. The superconductor 10 is then formed over each such semiconductor structure 4, covering part or all of the perimeter of the line along some or all of the length of the line. Each such semiconductor structure 4 and its respective superconductor coating 10 thus forms a respective semiconductor-superconductor nanowire. A network of such nanowires may be formed over the wafer 2 and can be arranged to form a topological quantum computing device comprising one or more topological qubits. In operation, Majorana zero modes (MZMs) and hence the topological regime may be induced in parts of some or all of the nanowires by means of a magnetic field and cooling to a temperature at which the superconductor 10 exhibits superconducting behaviour. In embodiments the inducement of the MZMs and topological regime may further comprise gating with an electromagnetic potential. Structures for forming qubits and the inducement of MZMs and the topological regime in a semiconductor-superconductor nanowire are, in them themselves, known in the art.

FIG. 5d illustrates an example with both the superconductor layer 10 and the oxide layer 8. The superconductor 10 may be formed on or over the semiconductor 4 of the nanowire, around some or all of the perimeter of the semiconductor 4 along some or all of its length. The oxide 8 may be formed on or over some or all of the superconductor 10, around some or all of the perimeter of the nanowire along some or all of its length.

In further examples, there could be other alternative or additional layers formed over the semiconductor 4, such as conductive vias between the semiconductors 4, and/or between the semiconductors 4 and one or more other components. As another example, an upper protective layer of plastic or wax may be formed over the whole structure.

Note that the FIGS. 5a to 5d are schematic and the shapes and dimensions shown therein are not intended to be limiting.

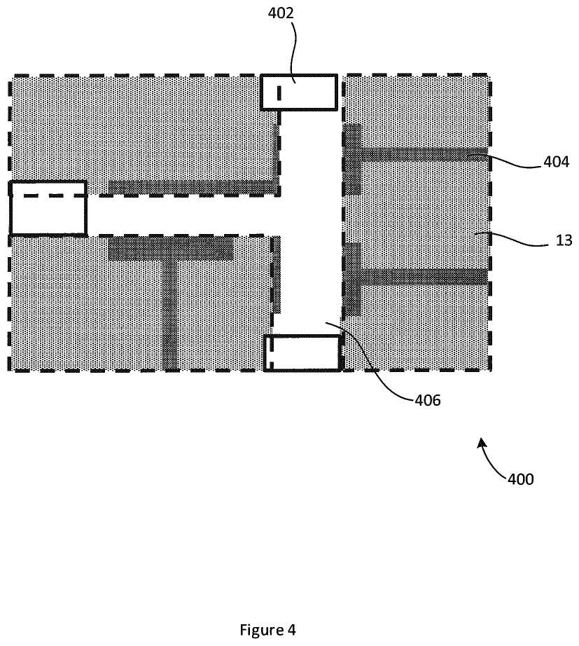

FIG. 4 shows a schematic top-view of a T-shaped SE//SU nanowire structure 406 and additional elements which form a quantum circuit 400. The SE//SU nanowires 406 are formed from lengths of semiconductor which have, at least in part, been coated with a superconductor. The semiconductor may be formed on the substrate 13 via SAG or they may be mechanically transferred onto the substrate 13.

Contacts 402 of the quantum circuit 400 have been added to the SE//SU nanowires, to allow electrical connection therewith. Sidegates 404 are shown which are formed of a gating material. These sidegates are designed for manipulating the SE//SU nanowires, and—in the context of topological quantum computing, for example—for manipulating Majorana zero modes hosted by the SE//SU nanowires, in order to perform quantum computations.

As discussed above, the disclosed technique may be used to deposit a number of different materials on the substrate 13. It will be appreciated that the substrate 13 shown in FIGS. 1 and 3 may comprise a semiconducting material which will form the nanowire. The disclosed technique, therefore, may be used to deposit the superconductor material on the semiconductor present in order to form the SE//SE nanowires.

In some embodiments, the above described technique may be used to deposit the semiconducting material, which will form the SE//SU nanowire, on the substrate 13.

The disclosed technique may also be used to deposit the gating material used to form the sidegates 404. In such a use, the deposition material may be a metal.

Additionally or alternatively, the deposition material may be a superconductor or metal for forming the contacts 402 of the quantum circuit 400.

Some structures require multiple layers of material to be deposited on the substrate 13. These layers may be formed of the same deposition material or they may be formed of different materials. The same set-up and method as described above can be used to deposit these additional layers of deposition material on the substrate 13. If the same deposition areas 17 are required for subsequent depositions, the same stencil mask 16 can be used. If a different deposition pattern, that is the pattern created by the deposition areas 17 when using a stencil mask 16, are required, then the stencil mask 16 can be replaced with a second stencil mask 16 which has a different pattern of apertures, so creates a different deposition pattern on the substrate 13.

FIG. 4 shows one example of a plan view of a quantum circuit 400 with one or more elements formed via the techniques described above. This example is not limiting and that other layouts of quantum circuits may be formed by the above method. It will be appreciated that the skilled person would know of alternative methods for making MZMs.

It will be appreciated that the above embodiments have been described by way of example only.

More generally, according to one aspect disclosed herein there is provided a method for collimating a beam of material being deposited on a substrate at a deposition area of the substrate, the method comprising: masking the substrate with a stencil mask located at a mask distance from the substrate, the mask distance being the distance between a top face of the substrate and an outer face of the mask facing the substrate; and projecting the beam from a source cell located at a source distance from the mask, the source distance being the distance between the source cell and an outer face of the mask facing the source cell; wherein the stencil mask comprises two mask layers separated by a layer separation distance which is great than zero, each layer comprising a slit, the slits of the two layers having a width being aligned in a plane of the substrate.

In some embodiments, a first opening angle may be a function of the source distance and a width of the slit in a first of the two mask layers, and the slit in the second of the two mask layers may reduce the opening angle to a second opening angle which is a function of the layer separation distance and the width of the slit in the second of the two mask layers, wherein the deposition area may be a function of the second opening angle.

In some embodiments, for a given source cell width, source distance, and mask distance, the deposition area may be smaller when using the stencil mask than the deposition area when using a single mask layer of the stencil mask.

In some embodiments, the stencil mask may prevent the beam projected from the extremities of the source cell from being deposition on the substrate, such that the beam deposition on the substrate is projected from an effective source cell width which is smaller than the width of the source cell.

In some embodiments, the layer separation distance may be between 100 μm and 1 mm.

In some embodiments, the source cell may have a width of between 5 mm and 50 mm.

In some embodiments, the mask distance may be between 1 μm and 10 μm.

In some embodiments, the source distance may be between 20 cm and 1 m.

In some embodiments, each mask layer may have a thickness of between 20 nm and 200 nm.

In some embodiments, the stencil mask may comprise a separation layer which separates the two mask layers by the separation distance.

In some embodiments, the separation layer may comprise a void, the void being disposed between the slits in the two mask layers in the plane perpendicular to the beam and being wider than said slits.

In some embodiments, the source cell may comprise a deposition material and the beam may be a beam of the deposition material, wherein the deposition material is deposited at the deposition area of the substrate.

In some embodiments, the deposition material may be deposited on the substrate via directional deposition.

In some embodiments, the deposition material may be a superconductor.

In some embodiments, the separation layer may comprise one or more silicon wafers.

In some embodiments, the two mask layers may be made of silicon nitrite or silicon.

In some embodiments, the substrate may comprise a silicon wafer.

According to a second aspect disclosed herein, there is provided a stencil mask comprising: two mask layers; a separation layer which separates the two mask layers by a layer separation distance which is greater than zero; wherein each mask layer comprises a slit, the slits being aligned in a plane of the mask; wherein the separation layer comprises a void which is aligned with the slits in the plan of the mask and is wider than the slits.

In some embodiments, there may be provided a system for collimating a beam, the system comprising: the stencil mask; and a source cell for projecting a beam, the source cell being located at a source distance from the stencil mask, the source distance being the distance between the source cell and an outer face of the mask facing the source cell.

In some embodiments, the source cell may comprise a deposition material and the beam may be a beam of the deposition material; and the system may comprise a substrate on which the deposition material is deposited, the substrate being located at a mask distance, the mask distance being the distance between a top face of the substrate and an outer face of the mask facing the substrate, wherein the deposition material may be deposited at a deposition area of the substrate.

According to a third aspect of the present disclosure, there is provided a method for fabricating the stencil mask, the method comprising: growing a first of the two mask layers on a first wafer; patterning said first mask layer; growing a second of the two mask layers on a second wafer; patterning said second mask layer; and affixing the two wafers together, such that the two mask layers are separated by the two wafer layers, the two wafer layers having a combined thickness equal to the layer separation distance.

In some embodiments, the mask layer may be made of silicon nitride and the wafer may be made of silicon, wherein the mask layer may be grown on the wafer via low pressure chemical vapour deposition.

In some embodiments, the mask layer may be patterned using a lithographical technique.

Other variations and applications of the disclosed techniques may become apparent to the person skilled in the art once given the disclosure herein. The scope of the present disclosure us not limited by the above-described embodiments, but only by the accompanying claims.

1. A method for collimating a beam of material being deposited on a substrate at a deposition area of the substrate, the method comprising:
masking the substrate with a stencil mask located at a mask distance from the substrate, the mask distance being the distance between a top face of the substrate and an outer face of the mask facing the substrate; and
projecting the beam from a source cell located at a source distance from the mask, the source distance being the distance between the source cell and an outer face of the mask facing the source cell;
wherein the stencil mask comprises two mask layers separated by a layer separation distance which is great than zero, each layer comprising a slit, the slits of the two layers having a width being aligned in a plane of the substrate.

2. The method according to claim 1, wherein a first opening angle is a function of the source distance and a width of the slit in a first of the two mask layers, and the slit in the second of the two mask layers reduces the opening angle to a second opening angle which is a function of the layer separation distance and the width of the slit in the second of the two mask layers, wherein the deposition area is a function of the second opening angle.

3. The method according to claim 1, wherein the layer separation distance is between 100 μm and 1 mm.

4. The method according to claim 1, wherein the source cell has a width of between 5 mm and 50 mm.

5. The method according to claim 1, wherein the mask distance is between 1 μm and 10 μm.

6. The method according to claim 1, wherein the source distance is between 20 cm and 1 m.

7. The method according to claim 1, wherein each mask layer has a thickness of between 20 nm and 200 nm.

8. The method according to claim 1, wherein the stencil mask comprises a separation layer which separates the two mask layers by the separation distance.

9. The method according to claim 8, wherein the separation layer comprises a void, the void being disposed between the slits in the two mask layers in the plane perpendicular to the beam and being wider than said slits.

10. The method according to claim 1, wherein the source cell comprises a deposition material and the beam is a beam of the deposition material, wherein the deposition material is deposited at the deposition area of the substrate.

11. A stencil mask, comprising
a separation layer which separates the two mask layers by a layer separation distance which is greater than zero;
wherein each mask layer comprises a slit, the slits being aligned in a plane of the mask; wherein the separation layer comprises a void which is aligned with the slits in the plane of the mask and is wider than the slits.

12. The system for collimating a beam, comprising:
the stencil mask according to claim 11;
a source cell for projecting a beam, the source cell being located at a source distance from the stencil mask, the source distance being the distance between the source cell and an outer face of the mask facing the source cell.

13. The system according to claim 12, wherein the source cell comprises a deposition material and the beam is a beam of the deposition material; and
the system comprises a substrate on which the deposition material is deposited, the substrate being located at a mask distance, the mask distance being the distance between a top face of the substrate and an outer face of the mask facing the substrate, wherein the deposition material is deposited at a deposition area of the substrate.

14. A method for fabricating the stencil mask according to claim 11, the method comprising:
growing a first of the two mask layers on a first wafer;
patterning said first mask layer;
growing a second of the two mask layers on a second wafer;
patterning said second mask layer; and
affixing the two wafers together, such that the two mask layers are separated by the two wafer layers, the two wafer layers having a combined thickness equal to the layer separation distance.

15. The method according to claim 14, wherein the mask layer is patterned using a lithographical technique.

16. The method according to claim 2, wherein the layer separation distance is between 100 μm and 1 mm.

17. The method according to claim 16, wherein the source cell has a width of between 5 mm and 50 mm.

18. The method according to claim 17, wherein the mask distance is between 1 μm and 10 μm.

19. The method according to claim 18, wherein the stencil mask comprises a separation layer which separates the two mask layers by the separation distance.

20. The method according to claim 2, wherein the stencil mask comprises a separation layer which separates the two mask layers by the separation distance and the separation layer defines a void disposed between the slits in the two mask layers in the plane perpendicular to the beam and being wider than said slits.
